(19) United States
(12) Patent Application Publication
(10) Pub. No.: US 2026/0040911 A1
(43) Pub. Date: Feb. 5, 2026

(54) BONDED SEMICONDUCTOR STRUCTURES, AND FABRICATION METHODS THEREOF

(71) Applicant: Qorvo US, Inc., Greensboro, NC (US)

(72) Inventors: Krishna Bahadur Chetry, High Point, NC (US); Michael Scott Carroll, Jamestown, NC (US)

(21) Appl. No.: 19/229,225

(22) Filed: Jun. 5, 2025

Related U.S. Application Data
(60) Provisional application No. 63/677,205, filed on Jul. 30, 2024.

(51) Int. Cl. H01L 23/00; H01L 21/768; H01L 23/48; H01L 25/065

(52) U.S. Cl. CPC H01L 24/05; H01L 21/76898; H01L 23/481; H01L 24/03; H01L 24/08; H01L 24/80; H01L 25/0657; H01L 2224/03002; H01L 2224/0311; H01L 2224/05548; H01L 2224/08145; H01L 2224/80895; H01L 2224/80896; H01L 2225/06544; H01L 2225/06565

(57) ABSTRACT

A bonded structure is provided. The bonded structure includes a first stack structure on a substrate, a second stack structure over the first stack structure, and a bonding interface between the first stack structure and the second stack structure. The second stack includes a via structure extending in the second stack structure and towards the bonding interface, the via structure having a first width closer to the bonding interface and a second width further away from the bonding interface. The first width is greater than the second width.

### CROSS-REFERENCE TO RELATED APPLICATIONS

The present application claims the benefit of U.S. Provisional App. No. 63/677,205, entitled “BONDED SEMICONDUCTOR STRUCTURES, AND FABRICATION METHODS THEREOF” and filed on Jul. 30, 2024, which is hereby incorporated by reference in its entirety.

### FIELD OF THE INVENTION

This disclosure relates to semiconductor fabrication. In particular, this disclosure relates to bonded semiconductor structures, and method for forming these structure.

### BACKGROUND

Fabrication is a crucial part of radio frequency (RF) technologies because it involves the creation of electronic devices and components that operate at high frequencies, typically in the range of several 337

hundred megahertz to several gigahertz. RF fabrication can produce dies that function as amplifiers, oscillators, filters, antennas, etc. The dies can be integrated into a RF to implement different functionalities of the RF device. As the RF devices continue to scale down, there is an increasing demand for die-shrinkage and performance enhancement in RF technology. However, with existing technology, there is a limitation in further reducing the die dimensions and adding more component for performance enhancement at the same time.

Therefore, there is a need to improve integration level of RF devices while at least maintaining their performance.

### SUMMARY

Aspects of the disclosure include a bonded structure. The bonded structure includes a first stack structure on a substrate, a second stack structure over the first stack structure, and a bonding interface between the first stack structure and the second stack structure. The second stack comprises a via structure extending in the second stack structure and towards the bonding interface, the via structure having a first width closer to the bonding interface and a second width further away from the bonding interface. The first width is greater than the second width.

In some embodiments, the first stack structure comprises a first device layer over the substrate; a first interconnect layer over the first device layer, and a first bonding layer over the first interconnect layer and in contact with the bonding interface.

In some embodiments, the second stack structure comprises a second bonding layer in contact with the bonding interface, a semiconductor layer over the bonding layer, a second device layer over the semiconductor layer, and a second interconnect layer over the second device layer. The via structure extends through the second device layer, the semiconductor layer, and into the second bonding layer.

In some embodiments, the second bonding layer comprises, a metal layer in contact with the via structure, and a plurality of bonding contacts in contact with the metal layer and the bonding interface.

In some embodiments, the via structure has a length in a range of between about 4 μm and about 20 μm along a first direction perpendicular to a surface of the substrate, and the first width and the second width are in a range of between about 2 μm and about 100 μm along a second direction parallel to the surface of the substrate.

Aspects of the present disclosure provide a method to form a bonded structure. The method includes forming a first bonding structure having a first device layer over a substrate, a first interconnect layer over the first device layer, and a first bonding layer over the first device layer. The method also includes forming a second bonding structure having a second bonding layer, a second device structure over the second bonding layer, and a second interconnect layer over the second device layer. The method also includes bonding the first bonding structure with the second bonding structure by bonding the first bonding layer with the second bonding layer.

In some embodiments, the forming of the second bonding structure includes forming the second device layer over a second substrate, forming an initial interconnect layer over the second device layer, and bonding a carrier wafer over the initial interconnect layer.

In some embodiments, the bonding of the carrier wafer includes forming a temporary bonding layer over the initial interconnect layer, and bonding the carrier wafer on the temporary bonding layer.

In some embodiments, the temporary bonding layer includes an infrared (IR) release layer.

In some embodiments, the forming of the second bonding layer includes thinning the second substrate to form a semiconductor layer, and wherein the thinning comprises at least one of a grinding process, a chemical mechanical polishing (CMP) process, or an etching process.

In some embodiments, the second substrate comprises a silicon-on-insulator (SOI) wafer.

In some embodiments, the forming of the second bonding layer comprises thinning the second substrate by removing a base substrate of the SOI wafer.

In some embodiments, the forming of the second bonding layer includes depositing a dielectric layer over the semiconductor layer, and forming a via structure through the dielectric layer and the second device layer and in contact with the initial interconnect layer through a damascene process.

In some embodiments, the forming of the second bonding layer comprises depositing a second dielectric layer over the via structure, and forming a metal layer in the second layer and in contact with the via structure through another damascene process.

In some embodiments, the forming of the second bonding layer includes depositing a third dielectric layer over the metal layer, and forming a plurality of first bonding contacts in the third dielectric layer and in contact with the metal layer.

In some embodiments, the forming of the plurality of bonding contacts comprises, forming, in the third dielectric layer, a plurality of openings that expose the metal layer, and plating a same metal material as the metal layer to fill the plurality of openings.

In some embodiments, the forming of the first bonding layer comprises: forming a fourth dielectric layer over the first interconnect layer; and forming another plurality of second bonding contacts in the fourth dielectric layer, locations of the plurality of first bonding contacts corresponding to locations of the plurality of second bonding contacts.

In some embodiments, the method further includes bonding the first bonding structure and the second bonding structure by bonding the plurality of first bonding contacts and the plurality of second bonding contacts.

In some embodiments, the method further includes applying infrared light on the second bonding structure to remove the temporary bonding layer and the carrier substrate.

In some embodiments, the method further includes forming an interconnect structure over the second bonding structure, the interconnect structure being electrically connected to the second interconnect layer.

### BRIEF DESCRIPTION OF THE DRAWINGS

FIG. 1A illustrates an exemplary bonded structure, according to embodiments of the present disclosure.

FIG. 1B shows an enlarged cross-sectional view of a via structure in the bonded structure shown in FIG. 1A, according to embodiments of the present disclosure.

FIG. 2 illustrates another exemplary bonded structure, according to embodiments of the present disclosure.

FIGS. 3A-3K illustrate different stages of a fabrication process to form a bonded structure, according to embodiments of the present disclosure.

FIG. 4 illustrates a flowchart of an exemplary fabrication process for forming a bonded structure, according to embodiments of the present disclosure.

### DETAILED DESCRIPTION

The following detailed description is illustrative in nature and is not intended to limit the scope, applicability, or configuration of inventive embodiments disclosed herein in any way. Rather, the following description provides practical examples, and those skilled in the art will recognize that some of the examples may have suitable alternatives. Embodiments will hereinafter be described in conjunction with the appended drawings, which are not to scale (unless so stated), wherein like numerals/letters denote like elements. However, it will be understood that the use of a number to refer to a component in a given drawing is not intended to limit the component in another drawing labeled with the same number. In addition, the use of different numbers to refer to components in different drawings is not intended to indicate that the different numbered components cannot be the same or similar to other numbered components. Examples of constructions, materials, dimensions and fabrication processes are provided for select elements and all other elements employ that which is known by those skilled in the art.

As used herein, the term “about” refers to a given amount of value that may vary based on the particular technology node associated with the semiconductor device. Based on a particular technology node, the term “about” can refer to a given amount of value that varies, for example, within 10-30% of the value (e.g., ±10%, ±20%, or ±20% of that value, or ±30%).

Reference will now be made in greater detail to various embodiments of the subject matter of the present disclosure, some embodiments of which are illustrated in the accompanying drawings.

As previously mentioned, there is a limitation in further reducing the die dimensions and adding more component for performance enhancement at the same time, in existing RF fabrication technologies. In order to overcome this limitation, this disclosure provides a novel approach to connect the devices in the vertical direction using wafer-to-wafer hybrid bonding. In this approach, a three-dimensional (3D) stack is created between multiple device layer connected through metal vias leading to significant device area density.

Embodiments of the present disclosure provide a front-to-back three-dimensional integrated circuit (3DIC) technology that allows the fronts side of the bottom wafer to connect with the back side of the top wafer, to form a bonded structure using the 3DIC technology. With this technique, the stacking can continue for multiple layer configuration unlike the existing wafer-to-die bonding. This approach also offers high alignment precision as it is much easier to align wafer-to-wafer compared to die-to-wafer. In addition, rather than going through a die selection followed by a die bonding process, wafer-to-wafer bonding leads to high throughput in the process flow. As shown in the embodiments, existing integration technologies often use a front-side through-silicon via (TSV) process from the top side of top wafer, which can be challenging and costly. The disclosed process uses a back-side TSV via on the top wafer, which is more cost-effective. This process uses an advanced temporary bonding process with infrared (IR) release layer which enables desirably high precision layer transfer from the top wafer layers to the bottom wafer.

Embodiments of the present disclosure provide process flows to create the wafer level device structures for top and bottom wafer. The process flows also include top wafer temporary bonding with carrier wafer and backside thinning of the Si substrate, and back-side Cu via through the top wafer to connect the bottom wafer. The process flows further include hybrid bonding between the back side of the top wafer to the front side of the back wafer. Multiple wafers can be added by repeating the process. Bumping and final packaging process for the completion of the packaging process is also provided.

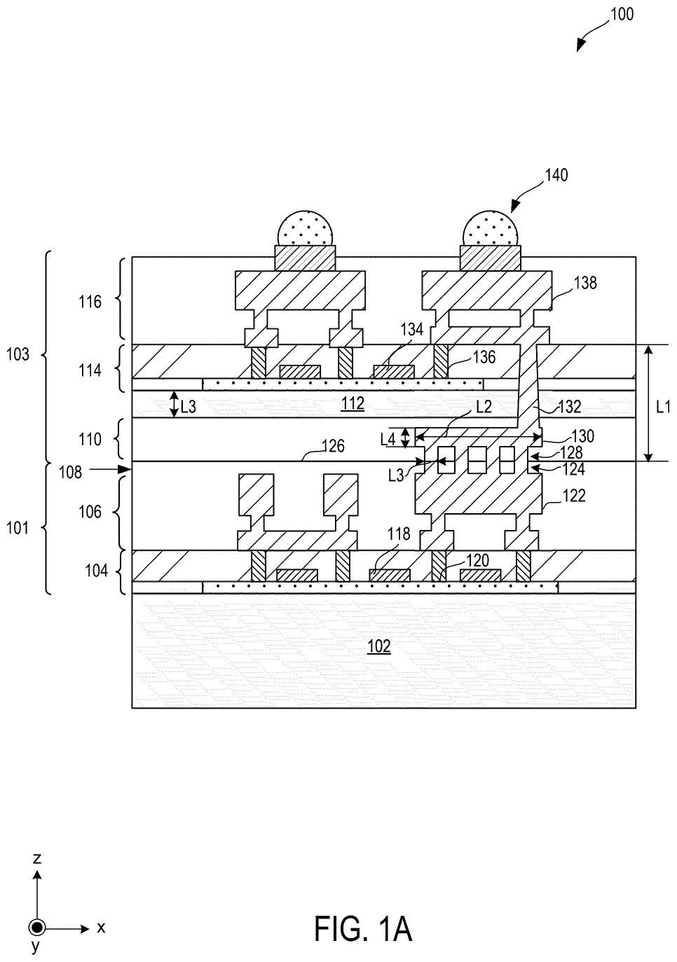

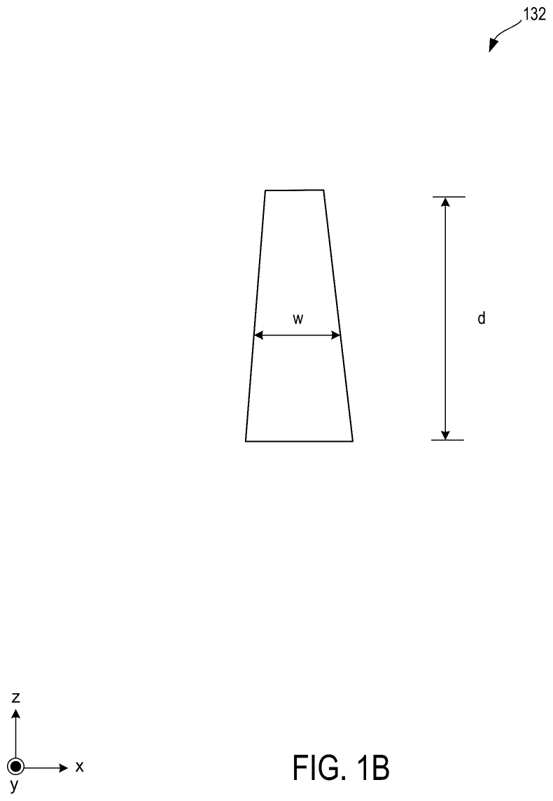

FIG. 1 illustrates an exemplary bonded structure 100, according to embodiments of the present disclosure. Bonded structure 100 may include a substrate 102, a first stack structure 101 over substrate 102, and a second stack structure 103 over first stack structure 101. Bonded structure 100 may also include a bonding interface 126 between and in contact with first stack structure 101 and second stack structure 103.

Substrate 102 may provide a base for forming the stack structures over and include a suitable material such as a semiconductor material (e.g., silicon, germanium, silicon carbide, gallium arsenide, indium arsenide, indium phosphide, silicon germanium, silicon germanium carbide, gallium arsenic phosphide, gallium indium phosphide), glass, carbon, plastic, or a combination thereof. In some embodiments, substrate 102 includes silicon. In some embodiments, substrate 102 includes a radio frequency (RF) silicon-on-insulator (SOI) wafer with high resistivity handle wafer (e.g., with resistivity greater than 3000 ohm-cm) and buried oxide (e.g., having a thickness of about 0.1 μm to about 1 μm). In some embodiments, substrate 102 includes a bulk silicon wafer (e.g., with resistivity around 10 Ohm-cm).

First stack structure 101 may include a device layer 104, an interconnect layer 106 over device layer 104, and a bonding layer 108 over interconnect layer 106. Device layer 104 may also be referred to as a front-end-of-line (FEOL) layer which may include a plurality of functional elements 118. For example, device layer 104 may include a dielectric layer, and the plurality of functional elements 118 that form RF filters, transmitters, receivers, transceivers, amplifiers, etc., embedded in the dielectric material. In various embodiments, functional elements 118 may include n type field effect transistors (n-FETs), p type field effect transistors (p-FETs), capacitors, resistors, inductors, and/or other functional devices. Device layer 104 may also include a plurality of vias 120 that electrically connects functional elements 118 with interconnects 122 in an interconnect layer 106 over device layer 104. Vias 120 may transmit signals (e.g., electrical signals, RF signals, etc.) between functional elements 118 and interconnects 122. The dielectric layer may include a suitable dielectric material (e.g., of low dielectric constant) such as silicon oxide, silicon nitride, silicon oxynitride, or any combination. Functional elements 118 and vias 120 may include various semiconductor materials, piezoelectric materials, metals, organic materials, inorganic materials, etc. In some embodiments, a bottom surface (e.g., facing substrate 102) of device layer 104 is in contact with substrate 102, and a top surface (e.g., facing away from substrate 102) of device layer 104 is in contact with interconnect layer 106. In some embodiments, first stack structure 101 as well as substrate 102 are part of a wafer, and device layer 104 includes one or more dies.

Interconnect layer 106 may also be referred to as a back-end-of-line (BEOL) layer, and may include a dielectric layer and a plurality of interconnects 122 embedded in the dielectric layer. Interconnects 122 may be electrically connected to vias 120 of device layer 104 for transmitting signals (e.g., electrical signals, RF signals, etc.) from device layer 104 to bonding layer 108. Although not shown, interconnect layer 106 may also include various routings that route signals from a functional element 118 to a desired location in interconnect layer 106. The dielectric layer may include silicon oxide, silicon nitride, silicon oxynitride, or any combination. Interconnects 122 (and any routings) may include one or more metallization layers, formed by various conductive materials such as metals, e.g., copper (Cu), aluminum (Al), gold (Au), tungsten (Wu), AlCu, and silver (Ag). In some embodiments, a bottom surface (e.g., facing substrate 102) of interconnect layer 106 is in contact with the top surface of device layer 104, and a top surface (e.g., facing away from substrate 102) of interconnect layer 106 may be in contact with a bonding layer 108.

Bonding layer 108 may include a dielectric layer and a plurality of bonding contacts 124 (e.g., bonding pads) embedded in the dielectric layer. Bonding layer 108 may be electrically connected to interconnect layer 106 and bonding layer 110, and may transmit signals (e.g., electrical signals, RF signals, etc.) from interconnects 122 to second stack structure 103. Bonding contacts 124 may be in contact with bonding contacts 128 of second stack structure 103 at bonding interface 126. In some embodiments, bonding contacts 124 may be distributed in the x-direction and may be in contact with a metal routing layer (not shown), the metal routing layer may further be electrically connected to interconnects 122. In some embodiments, a dimension L3 of bonding contact 124, along the x-direction may be in a range of between about 0.2 μm and about 4 μm. The dielectric layer may include silicon oxide, silicon nitride, silicon oxynitride, silicon carbon nitride, or any combination. Bonding contacts 124 may include various conductive materials such as metals, e.g., copper (Cu), aluminum (Al), gold (Au), tungsten (W), AlCu, and silver (Ag).

Second stack structure 103 may include a bonding layer 110, a semiconductor layer 112 over bonding layer 110, a device layer 114 over semiconductor layer 112, and an interconnect layer 116 over device layer 114. In some embodiments, element 112 includes a silicon oxide layer if element 112 is formed/thinned from a silicon-on-oxide (SOI) wafer. Second stack structure 103 may also include a via structure 132 extending from interconnect layer 116 to bonding layer 110, electrically connecting interconnect layer 116 and bonding layer 110. Bonding layer 110 may be in contact with bonding layer 108 at bonding interface 126. Bonding layer 110 may include a dielectric layer, a metal routing layer 130 embedded in the dielectric layer, and a plurality of bonding contacts 128 (e.g., bonding pads) embedded in the dielectric layer and in contact with metal routing layer 130. Bonding layer 110 and bonding layer 108 may be in contact with each other at bonding interface 126 via hybrid bonding, such that the dielectric materials of bonding layers 108 and 110 are bonded together, and bonding contacts 124 and 128 are bonded together, at bonding interface 126. Bonding layer 110 may be electrically connected to first stack structure 101 and an interconnect layer 116 of second stack structure 103. Bonding layer 110 may transmit signals (e.g., electrical signals, RF signals, etc.) from bonding contacts 124 to second stack structure 103.

In some embodiments, metal routing layer 130 may extend in the x-direction, and have a dimension L2 (e.g., length) in a range of about 2 μm and about 100 μm. In some embodiments, metal routing layer 130 may have a dimension L4 (e.g., thickness) in a range of about 0.1 μm and about 1 μm in the z-direction. Bonding contact 128, in contact with metal routing layer 130, may be distributed at any suitable location on bonding interface 126 along the x-direction, to form contact with bonding contacts 124. In some embodiments, bonding contact 128 may have a dimension L3 along the x-direction, same as bonding contact 124. The dielectric layer may include silicon oxide, silicon nitride, silicon oxynitride, or any combination. Bonding contacts 128 and metal routing layer 130 may include various conductive materials such as metals, e.g., copper (Cu), aluminum (Al), gold (Au), tungsten (W), AlCu, and silver (Ag).

Metal routing layer 130 may be electrically connected to (or in contact with) via structure 132, which extends along the z-direction to interconnect layer 116 of second stack structure 103. Via structure 132 may have a trapezoid shape with a width w (e.g., in the x-direction) decreasing in the z-direction from bonding layer 110 to interconnect layer 116. In some embodiments, via structure 132 extends from the interface between interconnect layer 116 and device layer 114 to a position in bonding layer 110. The position may be between the top surface and the bottom surface of bonding layer 110. FIG. 1B shows an enlarged cross-sectional view of via structure 132. Width w may decrease in the z-direction along the z-direction away from substrate 102. For example, via structure 132 may have a first width closer to substrate 102 and a second width further away from substrate 102, and the first width may be greater than the second width. In some embodiment, width w is in a range of about 0.5 μm and about 5 μm. Via structure 132 may have a length d in the z-direction and is in a range of about 2 μm and about 10 μm (e.g., between about 5 μm and about 7 μm). In some embodiments, length d is smaller than an existing TSV, which often typically has a length of at least about 20 μm. Because via structure 132 extends from interconnect layer 116 to bonding layer 110, and is formed from the back side of second stack structure 103, electrical connection between first stack structure 101 and second stack structure 103 can be achieved using a shorter via structure (e.g., 132), and the fabrication process can be simplified. For examples, issues such as uniformity degradation cause with etching deep openings can be alleviated or eliminated. In some embodiments, a top surface of bonding layer 110 is in contact with semiconductor layer 112, and a bottom surface of bonding layer 110 is in contact with bonding layer 108 at bonding interface 126. Via structure 132 may include a suitable material such as metals, e.g., copper (Cu), aluminum (Al), gold (Au), tungsten (W), AlCu, and silver (Ag). For example, via structure 132 includes copper.

In various embodiments, a distance between bonding contact 124/128 and via structure 132 can vary, depending on the design of the devices/structures. For example, the distance between bonding contact 124/128 and via structure 132 may be up to about 100 μm in some embodiments. The reason is that circuit nodes which need to be connected by bonding contacts 124 and 128 may be far apart in first stack structure 101 and second stack structure 103, due to factors such as the requirement for space efficient layouts on one or both of the stack structures.

Semiconductor layer 112 may include a suitable semiconductor material similar to substrate 102. In some embodiments, semiconductor layer 112 includes silicon. Semiconductor layer 112 may be formed by a thinning process of a semiconductor substrate, and may have a dimension (e.g., thickness) L3, along the z-direction, in a range of about 0.5 μm and about 5 μm. In some embodiments, a top surface of semiconductor layer 112 is in contact with device layer 114, and a bottom surface of semiconductor layer 112 is in contact with bonding layer 110. In some embodiments, element 112 includes a silicon oxide layer if element 112 is formed/thinned from a SOI wafer.

Device layer 114 may include a dielectric layer, and a plurality of functional elements 134 and a plurality of vias 136 embedded in the dielectric layer. Vias 136 may be electrically connected to interconnects 138 in interconnect layer 116 and functional elements 134, and may transmit signals (electrical signals, RF signals, etc.) between interconnect 138 and functional elements 134. Device layer 114 may be similar to or different from device layer 104. In some embodiments, a top surface of device layer 114 is in contact with interconnect layer 116, and a bottom surface of device layer 114 is in contact with semiconductor layer 112. In some embodiments, second stack structure 103 may be part of a wafer, and device layer 114 includes one or more dies. Detailed description of device layer 114 may be referred to that of device layer 104, and is not repeated herein. In some embodiments, a thickness L1, representing the total thickness of device layer 114, semiconductor layer 110, and bonding layer 110, may be in a range of about 4 μm and about 12 μm. For example, L1 may be about 8 μm. In some embodiments, L1 is significantly smaller than that (e.g., often at least 20 μm) of an existing TSV because of the small value of L3, which can be formed using the thinning process provided by this disclosure. The thinning process is described as follows.

Interconnect layer 116 may include a dielectric layer and a plurality of interconnects 138 embedded in the dielectric layer. Interconnects 138 may be electrically connected to vias 136 for transmitting signals (e.g., electrical signals, RF signals, etc.) from device layers 104 and 114 to an external circuit. In some embodiments, via structure 132 may be electrically connected to (or in contact with) an interconnects 138, to transmit signals generated by device layer 104 to interconnects 138, and further to an external circuit. In some embodiments, via structure 132 extends from the top surface of device layer 114, through semiconductor layer 112, and into bonding layer 110. Detailed description of interconnect layer 116 may be referred to that of interconnect layer 106, and is not repeated herein.

Bonded structure 100 may further include one or more interconnect structures 140 that are electrically connected to (or in contact with) interconnects 138. Interconnect structures 140 may include vias and corresponding soldering structures electrically connected to the vias. In an example, interconnect structure 140 includes an aluminum pad and a soldering ball in contact with the aluminum pad. Interconnect structures 140 may transmit signals generated by device layers 104 and 114 to an external circuit. In some embodiments, interconnect structures 140 may include conductive materials such as copper (Cu), aluminum (Al), tin (Sn), tungsten (Wu), gold (Au), silver (Ag), AlCu, and so on.

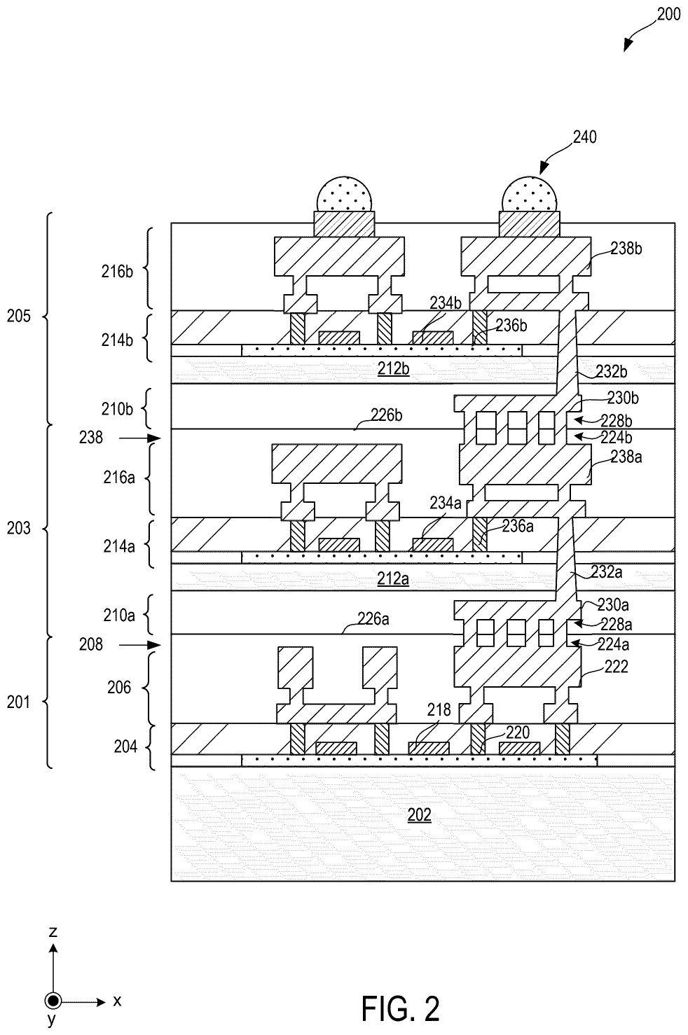

FIG. 2 illustrates another bonded structure 200, according to some embodiments of the present disclosure. Different from bonded structure 100, bonded structure 200 may include a first stack structure 201 over a substrate 202, a second stack structure 203 over first stack structure 201, and a third stack structure 205 over second stack structure 203. First stack structure 201 and second stack structure 203 may be in contact with each other at bonding interface 226a. Second stack structure 203 and third stack structure 205 may be in contact with each other at bonding interface 226b. Bonding interfaces 226a and 226b may be formed by hybrid bonding, and may be similar to bonding interface 126, and the detailed description is not repeated herein.

As shown in FIG. 2, first stack structure 201 includes a device layer 204, an interconnect layer 206 over device layer 204, and a bonding layer 208 over interconnect layer 206. Device layer 204 may include a dielectric layer and one or more functional elements 218 and vias 220. Interconnect layer 206 may include a dielectric material and one or more interconnects 222. Bonding layer 208 may include a dielectric layer and a plurality of bonding contacts 224a. Vias 220, electrically connected to functional elements 218, may be electrically connected to interconnect s 222 to transmit the signals generated by functional elements 218. First stack structure 201 may be similar to first stack structure 101. The detailed description of components of first stack structure 201 may be referred to their counterparts in first stack structure 101, and is not repeated herein.

Second stack structure 203 may include a bonding layer 210a, a semiconductor layer 212a, a device layer 214a, an interconnect layer 216a, and a bonding layer 238. Bonding layer 210a may include a dielectric layer, and a plurality of bonding contacts 228a in contact with bonding contacts 224a at bonding interface 226a. Bonding layer 210a may also include a metal routing layer 230a electrically connected to (or in contact with) bonding contacts 228a, and in contact with a via structure 232a that extends from interconnect layer 216a. Device layer 214a may include a dielectric layer, and a plurality of functional elements 234a and vias 236a. Interconnect layer 216a may include a dielectric layer, and a plurality of interconnects 238a. Bonding layer 238 may include a dielectric layer, and a plurality of bonding contacts 224b electrically connected to (or in contact with) interconnects 238a. Vias 236a may be electrically connected to functional elements 234a and interconnects 238a. Second stack structure 203 may also include via structure 232a extending in the z-direction, electrically connecting interconnects 238a and metal routing layer 230a. Interconnects 238a, through via structure 232a and vias 220 and 236a, may transmit signals generated by functional elements 218 and 234a with an external circuit. Bonding layer 210a, semiconductor layer 212a, device layer 214a, interconnect layer 216a, bonding layer 238, and via structure 232a may respectively be similar to bonding layer 110, semiconductor layer 112, device layer 114, interconnect layer 106, bonding layer 108, and via structure 132, and the detailed description is not repeated herein.

Third stack structure 205 may include a bonding layer 210b, a semiconductor layer 212b, a device layer 214b, an interconnect layer 216b, and one or more interconnect structures 240. Bonding layer 210b may include a dielectric layer, and a plurality of bonding contacts 228b in contact with bonding contacts 224b at bonding interface 226b. Bonding layer 210b may also include a metal routing layer 230b electrically connected to (or in contact with) bonding contacts 228b, and in contact with a via structure 232b that extends from interconnect layer 216b. Device layer 214b may include a dielectric layer, and a plurality of functional elements 234b and vias 236b. Interconnect layer 216b may include a dielectric layer, and a plurality of interconnects 238b. Vias 236b may be electrically connected to functional elements 234a and interconnects 238b. Interconnect structures 240 may include one or more vias and corresponding soldering structures that are electrically connected to interconnects 238b. Third stack structure 205 may also include via structure 232b extending in the z-direction, electrically connecting interconnects 238b and metal routing layer 230b. Interconnects 238b, through via structure 232b, via structure 232a, vias 220, vias 236a, and vias 236b may transmit signals generated by functional elements 218, 234a, and 234b to interconnect structures 240, which may be electrically connected to (e.g., soldered to) an external circuit. Bonding layer 210b, semiconductor layer 212b, device layer 214b, interconnect layer 216b, via structure 232b, and interconnect structures 240 may respectively be similar to bonding layer 110, semiconductor layer 112, device layer 114, interconnect layer 106, via structure 132, and interconnect structures 140, and the detailed description is not repeated herein.

As shown in FIGS. 1A and 2, at least two stack structures can be bonded together in the z-direction to form a bonded structure. One or more of the stack structures may include a respective device layer. The signals generated by the device layers can be transmitted vertically between adjacent stack structures using a via structure (e.g., 132, 232a, 232b). The via structure can have a significantly small length in the z-direction, compared to existing TSVs. The total thickness of the bonded structure is smaller, making the bonded structure more compact. In various embodiments, a bonded structure may include any suitable number of stack structures, and the disclosed via structure (e.g., 132, 232a, 232b) may be used to transmit signals between stack structures. The number of stack structure in a bonded structure should not be limited by the embodiments of the present disclosure.

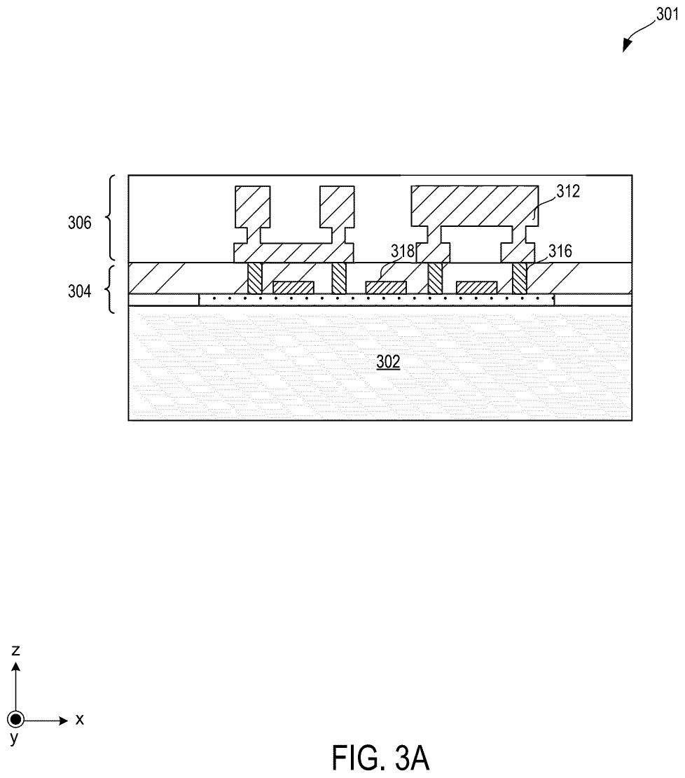

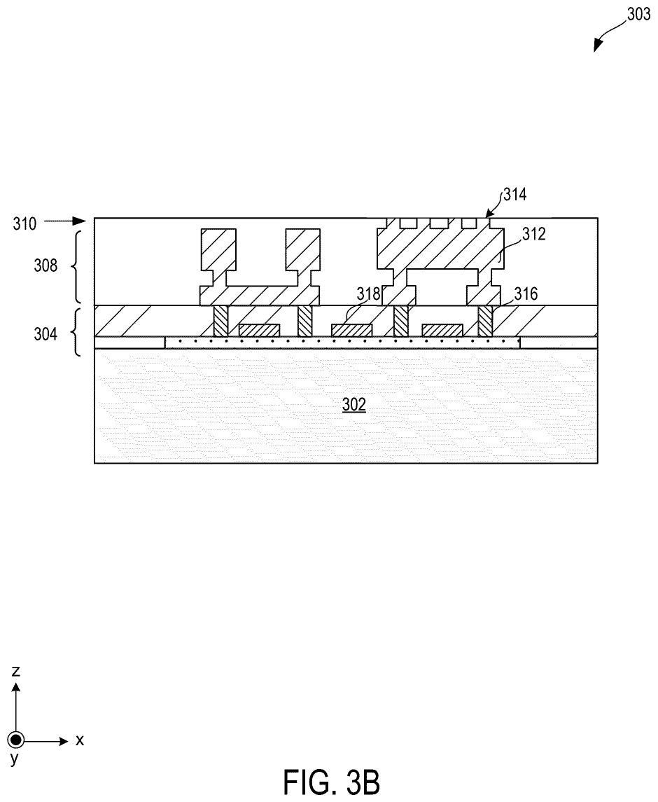

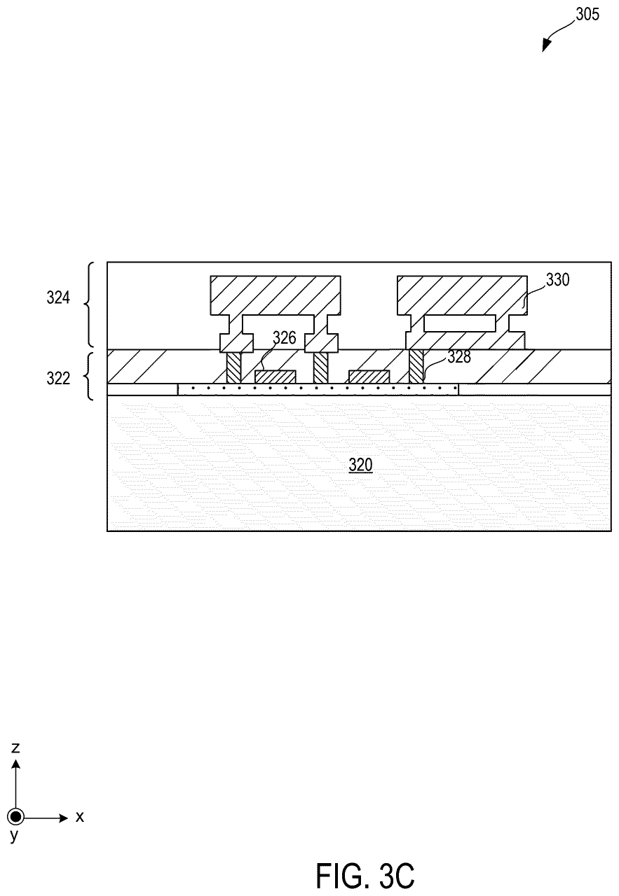

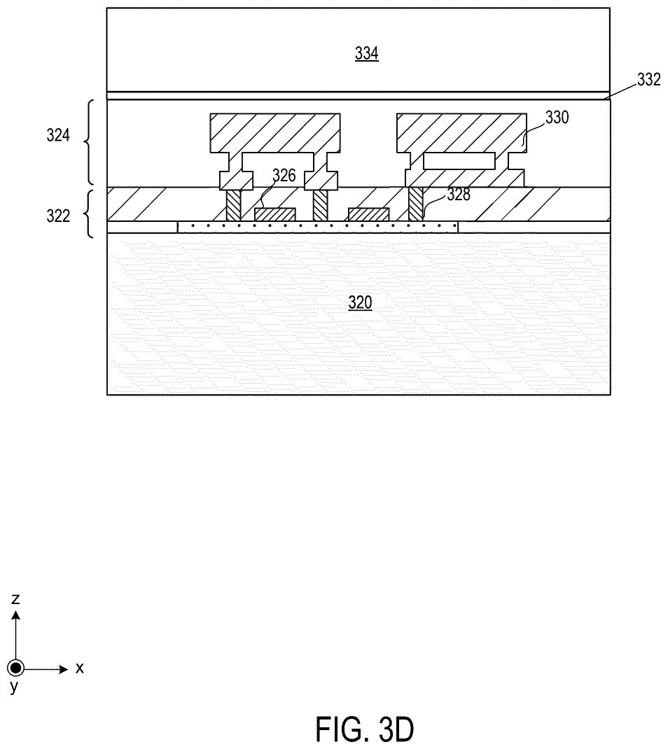

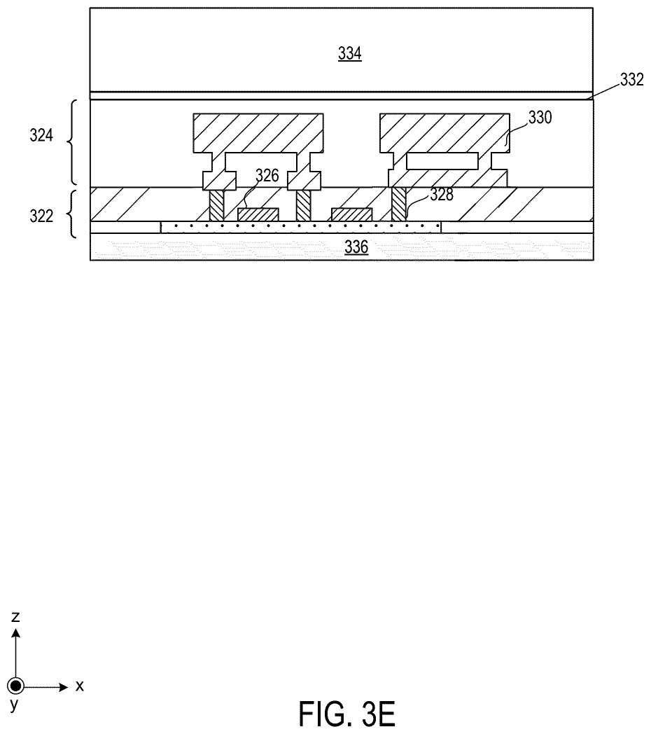

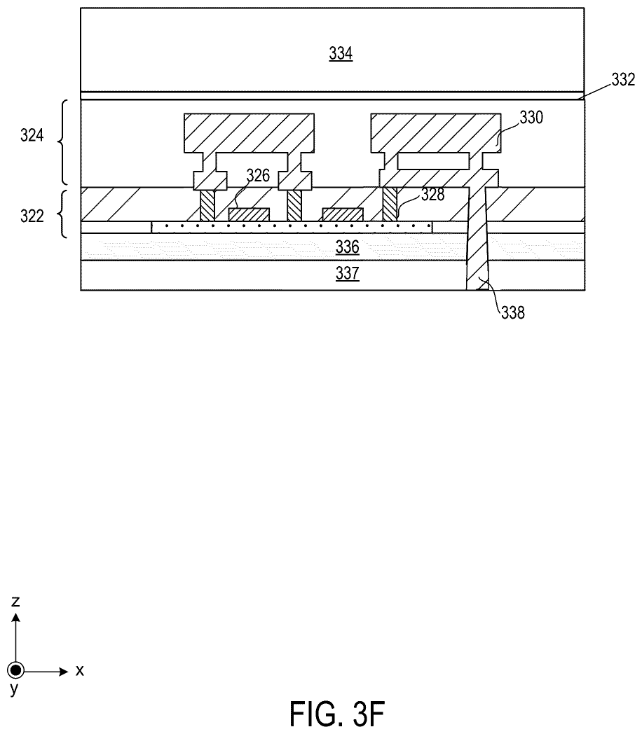

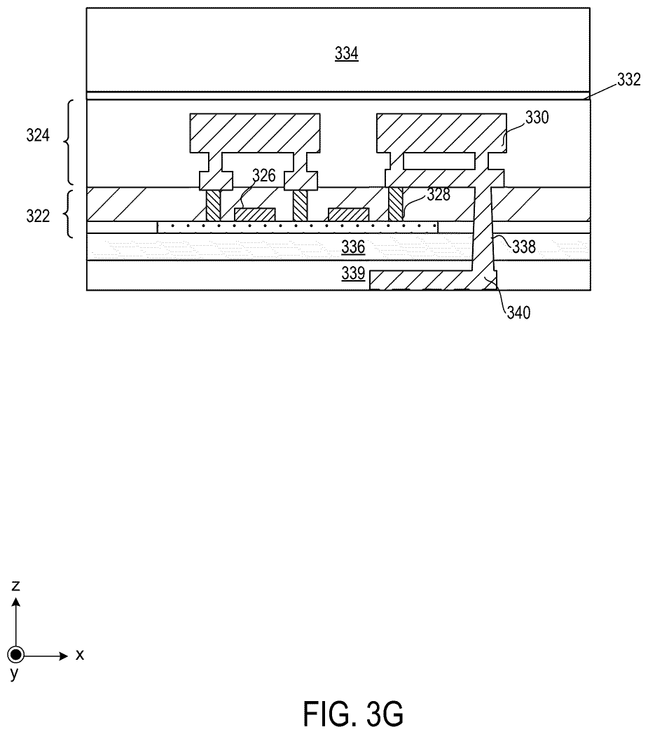

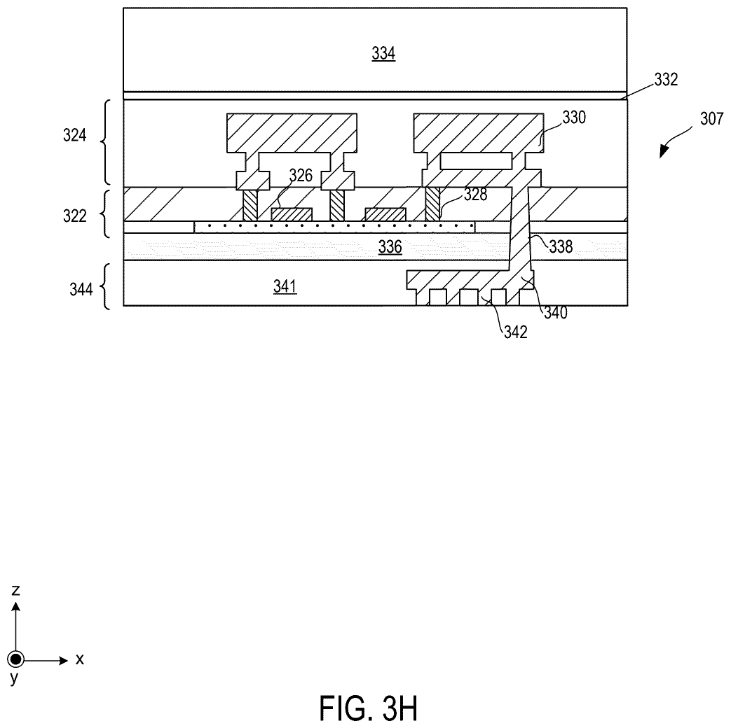

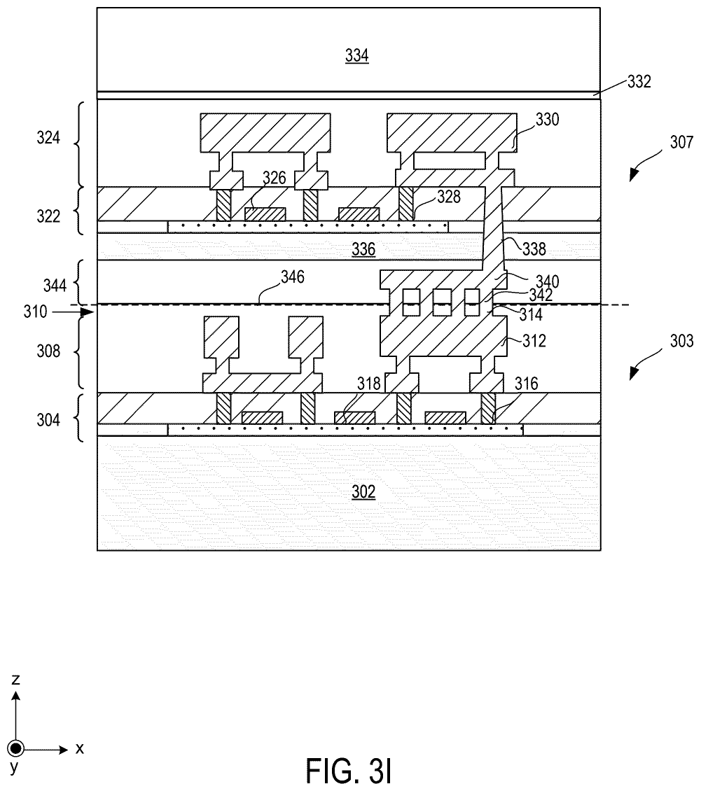

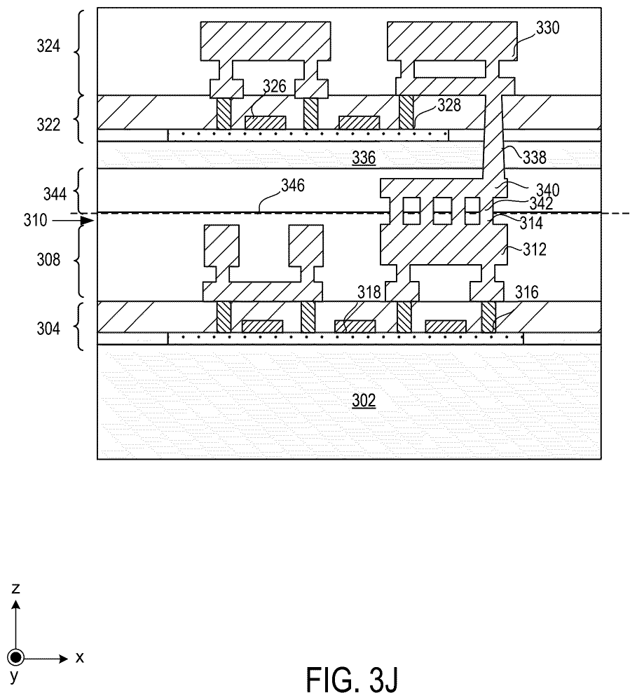

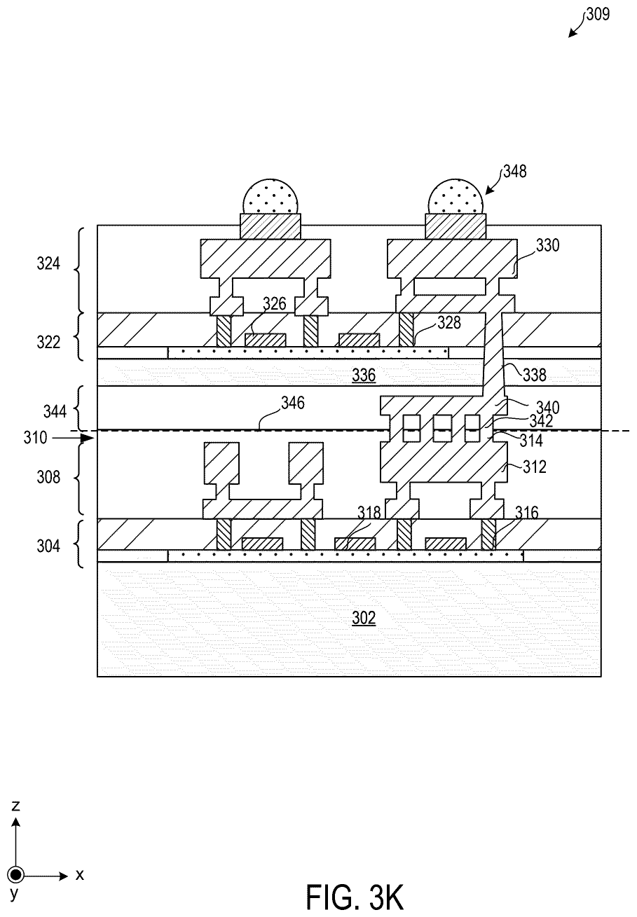

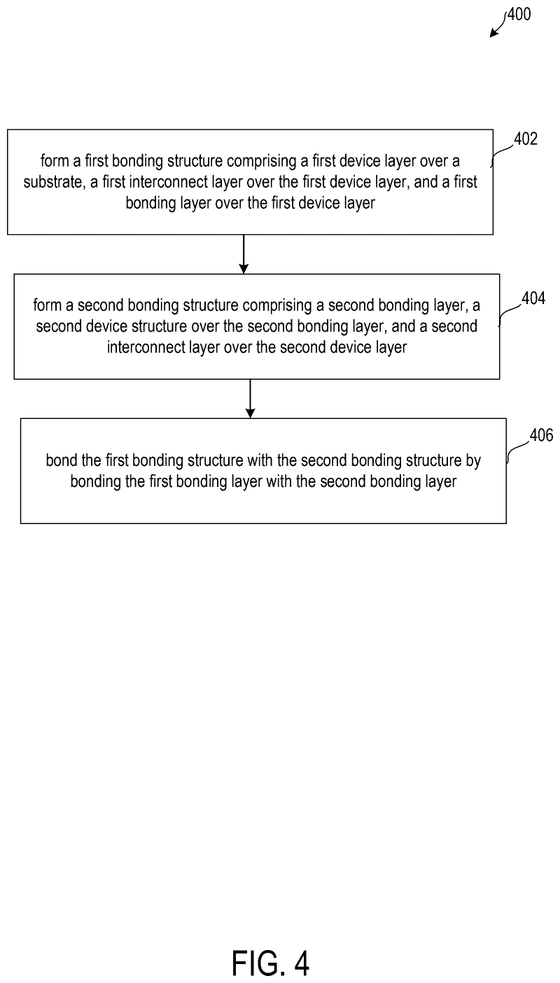

FIGS. 3A-3K illustrate structures of a bonded structure, similar to bonded structure 100, at different stages of an exemplary fabrication process. FIG. 4 is a flowchart of a method 400 for forming a bonded structure shown in FIG. 1A, according to some embodiments of the present disclosure. Method 400 is merely an example, and is not intended to limit the present disclosure beyond what is explicitly recited in the claims. Additional operations can be provided before, during, and after the method 400, and some operations described can be replaced, eliminated, or moved around for additional embodiments of method 400. It should be noted that, processes similar to method 400 can be used to form bonded structures with more than two stack structures, and the number of stack structure in a bonded structure should not be limited by the embodiments of the present disclosure. Method 400 will be described in more detail below.

At step 402, a first bonding structure is formed. The first bonding structure includes a first device layer over a substrate, a first interconnect layer over the first device layer, and a first bonding layer over the first device layer. FIGS. 3A and 3B show the corresponding structures.

As shown in FIG. 3A, an initial first bonding structure 301 is formed. Initial first bonding structure 301 may include a substrate 302, a device layer 304 over substrate 302, and an initial interconnect layer 306 over device layer 304. Substrate 302 may include a suitable semiconductor material such as silicon. Device layer 304 may include a dielectric material, one or more of functional elements 318 and one or more of vias 316 embedded in the dielectric material. Functional elements 318 may include RF filters, transmitters, receivers, transceivers, amplifiers, etc. The fabrication of functional device layer 304 may include a BOEL process. In some embodiments, substrate 302 includes a SOI wafer and device 304 may be formed over the oxide layer of the SOI wafer. In some embodiments, substrate 320 includes a bulk silicon wafer. Initial interconnect layer 306 may include a dielectric layer and one or more interconnects 312 embedded in the dielectric layer. Interconnects 312 may be formed to be electrically connected to corresponding vias 316. In some embodiments, initial interconnect layer 306 includes a plurality of metallization layers. For example, the number of metallization layers may range from 1 to about 10, and be a combination of any one(s) of thin aluminum layers, thin copper layers, and thick aluminum layers, and thick copper layers. Initial interconnect layer 306 may include a layer of dielectric material (about 0.5 μm to about 2 μm thick) deposited on the top of interconnects 312 to fully cover interconnects 312 (e.g., the metallization layer), creating a planar surface. In some embodiments, the fabrication of initial interconnect layer 306 may include a FEOL process.

In various embodiments, device layer 304 includes various semiconductor materials, metals, dielectric materials, organic materials, inorganic materials, etc., and initial interconnect layer 306 includes dielectric materials and metals. The forming of device layer 304 and initial interconnect layer 306 may include photolithography, dry etch, wet etch, chemical vapor deposition (CVD), physical vapor deposition (PVD), atomic layer deposition (ALD), electroplating, electroless plating, sputtering, soldering, grinding, chemical mechanical polishing (CMP), and/or a cleaning process.

As shown in FIG. 3B, a plurality of bonding contacts 314 may be formed in the dielectric material over interconnects 312. Bonding contacts 314 may be in contact with interconnects 312. In some embodiments, bonding contacts 314 includes a suitable metal such as copper (Cu). Bonding contacts 314 may serve as the electrical connection between adjacent bonding structures, and may be referred to as hybrid bond (HB) vias. A HB via may be in a range of about 1 μm to about 2 μm wide (e.g., in the x-direction) and about 0.5 μm to about 1 μm thick (e.g., in the z-direction). These dimensions may be adjusted, but the small size and height of the HB via may be advantageous as described later. In some embodiments, HB vias may be formed using a suitable etching process (e.g., oxide/nitride etch), Cu plating, and chemical mechanical polishing (CMP) processes. In some embodiments, the HB via process may be adjusted specifically to enable the hybrid bonding process described later, such as recessing the HB via surface slightly below the oxide surface.

First bonding structure 303 may then be formed. First bonding structure 303 may include substrate 302, device layer 304, interconnect layer 308, and bonding layer 310. Interconnect layer 308 may include interconnects 312 and the surrounding dielectric material. Bonding layer 310 may include bonding contacts 314 and the surrounding dielectric material.

Referring back to FIG. 4, at step 404, a second bonding structure is formed. The second binding structure includes a second bonding layer, a second device structure over the second bonding layer, and a second interconnect layer over the second device layer. FIGS. 3C-3H show the corresponding structures.

As shown in FIG. 3C, an initial second bonding structure 305 is formed. Initial second bonding structure 305 may include a substrate 320, a device layer 322 over substrate 320, and an initial interconnect layer 324 over device layer 322. Substrate 320 may include a suitable semiconductor material such as silicon. Device layer 322 may include a dielectric material, one or more of functional elements 326 and one or more of vias 328 embedded in the dielectric material. Functional elements 326 may include RF filters, transmitters, receivers, transceivers, amplifiers, etc. The fabrication of functional device layer 322 may include a BOEL process. In some embodiments, substrate 320 includes a SOI wafer and device 322 may be formed over the oxide layer of the SOI wafer. In some embodiments, substrate 320 includes a bulk silicon wafer. Initial interconnect layer 324 may include a dielectric layer and one or more interconnects 330 embedded in the dielectric layer. Interconnects 330 may be formed to be electrically connected to corresponding vias 328. In some embodiments, initial interconnect layer 324 includes a plurality of metallization layers. For example, the number of metallization layers may range from 1 to about 10, and be a combination of any one(s) of thin A1 layers, thin Cu layers, and thick A1 layers, and thick Cu layers. Initial interconnect layer 324 may include a layer of dielectric material (about 0.5 μm to about 2 μm thick) deposited on the top of interconnects 330 to fully cover interconnects 330 (e.g., the metallization layer), creating a planar surface. In some embodiments, the fabrication of initial interconnect layer 324 may include a FEOL process.

In various embodiments, device layers 322 and 304 may be similar or different. In some embodiments, devices layers 322 and 304 may be optimized to support different supply voltages and/or different operating frequencies. In some embodiments, same or different number of metallization layers may be formed in initial interconnect layers 306 and 324. The fabrication of second initial bonding structure 305 may be similar to that of first initial bonding structure 301, and the detailed description is not repeated herein.

As shown in FIG. 3D, a temporary bonding layer 332 is attached to second initial bonding structure 305, and a carrier wafer 334 is bonded to temporary bonding layer 332. In some embodiments, temporary bonding layer 334 is attached to the top surface (e.g., facing away from substrate 320) of initial interconnect layer 324, and carrier wafer 334 is attached to second initial bonding structure 305 via temporary bonding layer 332. In some embodiments, temporary bonding layer 332 includes an infrared (IR) release layer. Temporary bonding layer 332 may be applied on initial interconnect layer 324 using a film deposition process to deposit inorganic thin-film dielectric layers, which are designed to absorb IR light. In various embodiments, the film deposition process includes a chemical vapor deposition (CVD), a physical vapor deposition (PVD), an ion beam deposition (IBD), or any combination. In an example, IR Laser Cleave technology from EVG is used to form temporary bonding layer 332. Temporary bonding layer 332 may have a thickness (e.g., in the z-direction) of about a few nanometers up to about 1 μm. Carrier wafer 334 may include a suitable material with sufficient physical stiffness, and is sufficiently transparent to infrared light such that carrier wafer 334 can be subsequently removed using IR light later in the process. In some embodiments, carrier wafer 334 includes silicon.

As shown in FIG. 3E, substrate 320 may be thinned to form a semiconductor layer 336. In some embodiments, second initial bonding structure 305 may be mounted or handled using carrier wafer 334, to remove a desired substrate thickness of substrate 320 at its bottom surface (e.g., backside). In some embodiments, substrate 320 is thinned to about 20 μm using a grinding process. The grinding process may be performed in two phases: coarse grinding and fine grinding. In-situ monitoring of the thickness may be performed by using contact and non-contact gauges and the uniformity of the substrate thickness may be maintained with auto total thickness variation (TTV) control. A CMP may be used to smooth the surface and further reduce the substrate thickness. In some embodiments, chemical etching using tetramethylammonium hydroxide (TMAH) or similar etchant may be used to reduce the substrate thickness. In some embodiments, a wet etch and/or a dry etch is used. If substrate 320 is a bulk Si wafer, the final remaining substrate thickness may be about 0.5 μm to about 5 μm. If substrate 320 is a SOI, the entire silicon handle wafer/substrate can be removed, stopping on the buried oxide (BOX) layer.

As shown in FIG. 3F, a via structure 338 may be formed through the bottom surface (e.g., backside) of second initial bonding structure 305. A dielectric layer 337 may be deposited on semiconductor layer 336, e.g., at the bottom surface of second initial bonding structure 305. A suitable etching process (e.g., dry etch and/or wet etch) may be performed to for an opening through dielectric layer 337, semiconductor layer 336, and device layer 322, and exposing a corresponding interconnect 330. In some embodiments, the opening and interconnect 330 may be in contact with each other at the interface between initial interconnect layer 324 and device layer 322. In some embodiments, the opening and interconnect 330 may be in contact with each other between the top and bottom surfaces of initial interconnect layer 324. A suitable metal material, such as copper (Cu), may be deposited to fill the opening, using one or more of CVD, PVD, ALD, electroplating, electroless plating, sputtering, or any combination. Via structure 338 may be formed. A planarization process, such as CMP, may then be performed to remove excess materials on dielectric layer 337 and via structure 338.

In an example, dielectric layer 337 include silicon oxide and has a thickness (e.g., in the z-direction) of about 1 μm. Via structure 338 (e.g., a back-side Cu via) may include Cu, and may have a length d (e.g., referring back to FIG. 1B) of about 5 μm to about 7 μm tall and a width (e.g., w referring back to FIG. 1B) of about 4 μm wide. In some embodiments, via structure 338 is formed using a Cu damascene process. In some embodiments, via structure 338 may land on the M1 layer (thin Cu interconnect) to allow electrical connection.

As shown in FIG. 3G, a metal routing layer 340 may be formed. Another dielectric layer may be deposited on dielectric layer 337, e.g., at the bottom surface of second initial bonding structure 305, to form a dielectric layer 339. A suitable etching process (e.g., dry etch and/or wet etch) may be performed to form an opening through dielectric layer 339 and exposing via structure 338. In some embodiments, the opening and via structure 338 may be in contact with each other between the top and bottom surfaces of dielectric layer 339. A suitable metal material, such as copper (Cu), may be deposited to fill the opening, using one or more of CVD, PVD, ALD, electroplating, electroless plating, sputtering, or any combination. Metal routing layer 340 may be formed. A planarization process, such as CMP, may then be performed to remove excess materials on dielectric layer 339 and metal routing layer 340. In various embodiments, metal routing layer 340 has a suitable dimension in the x-direction to allow subsequent formation of bonding contacts at a desired location, for electrically connecting a desired interconnect in the adjacent bonding structure. In an example, metal routing layer 340 may be about 0.5 μm thick in the z-direction, and may be fabricated using a Cu damascene process.

As shown in FIG. 3H, a plurality of bonding contacts 342 may be formed. Another dielectric layer may be deposited on dielectric layer 339, e.g., at the bottom surface of second initial bonding structure 305, to form a dielectric layer 341. The material, dimensions, and fabrication process to form bonding contacts 342 may be similar to those of bonding contacts 314, and the detailed description is not repeated herein.

Second bonding structure 307 may then be formed. Second bonding structure 307 may include bonding layer 344, semiconductor layer 336, device layer 322, via structure 338, and interconnect layer 324. Interconnect layer 324 may include interconnects 330 and the surrounding dielectric material. Bonding layer 344 may include bonding contacts 342, metal routing layer 340, and the surrounding dielectric material.

Referring back to FIG. 4, at step 406, the first bonding structure is bonded with the second bonding structure by bonding the first bonding layer with the second bonding layer. FIGS. 3I-3K show the corresponding structures.

As shown in FIG. 3I, first bonding structure 303 and second bonding structure 307 may be bonded at a bonding interface 346. In some embodiments, bonding layers 344 and 310 are bonded via hybrid bonding such that the dielectric materials and metal materials of bonding layers 344 and 310 are bonded respectively. Bonding contacts 314 and 342 may be aligned and bonded to form electrical connection. The bonding of first bonding structure 303 and second bonding structure 307 may also be referred to as back-to-front bonding for bonding the front surface of first bonding structure 303 with the back surface of second bonding structure 307. In some embodiments, the hybrid bonding process includes applying heat and/or pressure on first bonding structure 303 and second bonding structure 307.

In an example, first bonding structure 303 and second bonding structure 307 are bonded using a hybrid oxide-copper bonding process. The location of HB vias (e.g., bonding contacts 314 and 342) of first bonding structure 303 and second bonding structure 307 may match exactly. The two bonding structures may be properly planarized such that when they are brought together, an intimate connection from covalent bonding will exist between all of the oxide regions (e.g., dielectric layers) in the bonding structures. Planarization may be performed using CMP. A cleaning process may be used to clean any particles from the surfaces of the two bonding structures, followed by plasma treatment to promote the bonding process. This is referred to as plasma-assisted hybrid bonding. The HB vias of the two bonding structures may be aligned together using a suitable wafer alignment tool. Following alignment, the hybrid bonding process is strengthened into a permanent bond using annealing process around 350 degrees Celsius.

As shown in FIG. 3J, the carrier wafer and the temporary bonding layer are removed. Carrier wafer 334 may be de-bonded from the bonded first bonding structure 303 and second bonding structure 307 using an IR release process. In some embodiments, IR light may be applied on the bonded first bonding structure 303 and second bonding structure 307. Carrier wafer 334 may be sufficiently transparent to IR light, allowing the temporary bond material to be heated to enable de-bonding.

As shown in FIG. 3K, interconnect structures 348 may be formed. A bonded structure 309 may be formed. Interconnect structures 348 may be formed over the bonded first bonding structure 303 and second bonding structure 307, e.g., over interconnect layer 324, to be electrically connected to interconnects 330. In some embodiments, interconnect structures 348 includes suitable vias (e.g., metal pads) electrically connected to interconnects 330, and soldering structures electrically connected to the corresponding via. In various embodiments, interconnect structures 348 includes copper (Cu), aluminum (Al), tin (Sn), gold (Au), silver (Ag), tungsten (W), AlCu, and so on. The fabrication of interconnect structures 348 may include photolithography, dry etch, wet etch, chemical vapor deposition (CVD), physical vapor deposition (PVD), atomic layer deposition (ALD), electroplating, electroless plating, sputtering, soldering, grinding, chemical mechanical polishing (CMP), and/or a cleaning process.

In various embodiments, more bonding structures, including back-side Cu vias (e.g., via structure 338) may be stacked along the z-direction. The fabrication of such bonded structures may be similar to the process of method 400, and the number of bonding structures are not limited by the embodiments of the present disclosure.

Those skilled in the art will recognize improvements and modifications to the preferred embodiments of the present disclosure. All such improvements and modifications are considered within the scope of the concepts disclosed herein and the claims that follow.

1. A bonded structure, comprising:
a first stack structure on a substrate;
a second stack structure over the first stack structure; and
a bonding interface between the first stack structure and the second stack structure, wherein the second stack comprises a via structure extending in the second stack structure and towards the bonding interface, the via structure having a first width closer to the bonding interface and a second width further away from the bonding interface, wherein the first width is greater than the second width.

2. The bonded structure of claim 1, wherein the first stack structure comprises:
a first device layer over the substrate;
a first interconnect layer over the first device layer; and
a first bonding layer over the first interconnect layer and in contact with the bonding interface.

3. The bonded structure of claim 1, wherein the second stack structure comprises:
a second bonding layer in contact with the bonding interface;
a semiconductor layer over the bonding layer;
a second device layer over the semiconductor layer; and
a second interconnect layer over the second device layer, wherein the via structure extends through the second device layer, the semiconductor layer, and into the second bonding layer.

4. The bonded structure of claim 3, wherein the second bonding layer comprises:
a metal layer in contact with the via structure; and
a plurality of bonding contacts in contact with the metal layer and the bonding interface.

5. The bonded structure of claim 1, wherein the via structure has:
a length in a range of between about 4 μm and about 20 μm along a first direction perpendicular to a surface of the substrate, and
the first width and the second width are in a range of between about 2 μm and about 100 μm along a second direction parallel to the surface of the substrate.

6. A method to form a bonded structure, comprising:
forming a first bonding structure comprising a first device layer over a substrate, a first interconnect layer over the first device layer, and a first bonding layer over the first device layer;
forming a second bonding structure comprising a second bonding layer, a second device structure over the second bonding layer, and a second interconnect layer over the second device layer; and
bonding the first bonding structure with the second bonding structure by bonding the first bonding layer with the second bonding layer.

7. The method of claim 6, wherein the forming of the second bonding structure comprises:
forming the second device layer over a second substrate;
forming an initial interconnect layer over the second device layer; and
bonding a carrier wafer over the initial interconnect layer.

8. The method of claim 7, wherein the bonding of the carrier wafer comprises:
forming a temporary bonding layer over the initial interconnect layer; and
bonding the carrier wafer on the temporary bonding layer.

9. The method of claim 8, wherein the temporary bonding layer comprises an infrared (IR) release layer.

10. The method of claim 7, wherein the forming of the second bonding layer comprises thinning the second substrate to form a semiconductor layer, and wherein the thinning comprises at least one of a grinding process, a chemical mechanical polishing (CMP) process, or an etching process.

11. The method of claim 7, wherein the second substrate comprises a silicon-on-insulator (SOI) wafer.

12. The method of claim 11, wherein the forming of the second bonding layer comprises thinning the second substrate by removing a base substrate of the SOI wafer.

13. The method of claim 10, wherein the forming of the second bonding layer comprises:
depositing a dielectric layer over the semiconductor layer; and
forming a via structure through the dielectric layer and the second device layer and in contact with the initial interconnect layer through a damascene process.

14. The method of claim 13, wherein the forming of the second bonding layer comprises:
depositing a second dielectric layer over the via structure; and
forming a metal layer in the second layer and in contact with the via structure through another damascene process.

15. The method of claim 14, wherein the forming of the second bonding layer comprises:
depositing a third dielectric layer over the metal layer; and
forming a plurality of first bonding contacts in the third dielectric layer and in contact with the metal layer.

16. The method of claim 15, wherein the forming of the plurality of bonding contacts comprises:
forming, in the third dielectric layer, a plurality of openings that expose the metal layer; and
plating a same metal material as the metal layer to fill the plurality of openings.

17. The method of claim 13, wherein the forming of the first bonding layer comprises:
forming a fourth dielectric layer over the first interconnect layer; and
forming another plurality of second bonding contacts in the fourth dielectric layer, locations of the plurality of first bonding contacts corresponding to locations of the plurality of second bonding contacts.

18. The method of claim 13, further comprising
bonding the first bonding structure and the second bonding structure by bonding the plurality of first bonding contacts and the plurality of second bonding contacts.

19. The method of claim 18, further comprising applying infrared light on the second bonding structure to remove the temporary bonding layer and the carrier substrate.

20. The method of claim 6, further comprising forming an interconnect structure over the second bonding structure, the interconnect structure being electrically connected to the second interconnect layer.
